(19) United States
(12) Patent Application Publication
(10) Pub. No.: US 2010/0149481 A1
(43) Pub. Date: Jun. 17, 2010

(54) MANUFACTURING METHOD OF MOLD AND METHOD FOR FORMING LIQUID CRYSTAL DISPLAY USING THE SAME

(75) Inventors: Byeong-Jin Lee, Seoul (KR); Bong-Kyun Kim, Incheon (KR); Hong-Sick Park, Suwon-si (KR); Gug-Rae Jo, Asan-si (KR); Chang-Hoon Kim, Cheonan-si (KR); Jong-Hyun Choung, Hwaseong-si (KR); Sun-Young Hong, Yongin-si (KR); Min-Uk Kim, Seongnam-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/475,083

(22) Filed: May 29, 2009

(30) Foreign Application Priority Data
Dec. 17, 2008 (KR) 10-2008-0128493

(51) Int. Cl. G03F 7/20; C23F 1/02; G02F 1/13

(52) U.S. Cl. 349/187; 430/320; 216/41

(57) ABSTRACT

The present invention relates to a liquid crystal display (LDC) and in particular, a method of manufacturing a mold to be used in LCDs. The method includes the following steps: forming a first photosensitive film on a substrate; etching the substrate by using the first photosensitive film as a mask to form a first groove; removing the first photosensitive film; forming a second photosensitive film covering the first groove on the substrate; and etching the substrate by using the second photosensitive film as a mask to form a second groove. The method, according to embodiments of the invention, helps reduce the time and/or cost of manufacturing a liquid crystal display.

### CROSS-REFERENCE TO RELATED APPLICATION

This application claims priority from and the benefit of Korean Patent Application No. 10-2008-0128493, filed on Dec. 17, 2008 which is hereby incorporated by reference for all purposes as if fully set forth herein.

### BACKGROUND OF THE INVENTION

1. Field of the Invention

Embodiments of the present invention relate to a manufacturing method of a mold, and a manufacturing method of a liquid crystal display using the mold.

2. Description of the Background

A liquid crystal display (LCD) is one of the most commonly used flat panel displays. An LCD can include two substrates with electrodes formed thereon and a liquid crystal layer interposed between the two substrates. A voltage may be applied to the electrodes to realign liquid crystal molecules of the liquid crystal layer to regulate transmittance of light passing through the liquid crystal layer.

Patterns in each layer of the LCD may be formed through a photolithography process. In the photolithography process, a photosensitive film may be formed on a target layer, and the photosensitive film may be exposed and developed through a mask. The target layer may subsequently be etched using a remaining portion of the photosensitive film as a mask.

However, the photolithography process suffers from several problems. For example, the photolithography process includes highly complex steps such as the exposure and developing steps which may, for example, take an excessively long time to execute leading to delays in the execution of the photolithography process. In addition, the photolithography process utilizes expensive equipment leading to greater costs.

The above information disclosed in this Background section is only for enhancement of understanding of the background of the invention and therefore it may contain information that does not form the prior art that is already known.

### SUMMARY OF THE INVENTION

Exemplary embodiments of the present invention relate to a method of manufacturing a mold used in manufacturing LCDs. The method for manufacturing the mold may reduce the time and/or cost of manufacturing a liquid crystal display.

Additional features of the exemplary embodiments will be set forth in the description which follows, and in part will be apparent from the description, or may be learned by practice of the invention.

Exemplary embodiments of the present invention disclose a manufacturing method of a mold. The method comprises forming a first photosensitive film on a substrate; etching the substrate by using the first photosensitive film as a mask to form a first groove; removing the first photosensitive film; forming a second photosensitive film covering the first groove on the substrate; and etching the substrate by using the second photosensitive film as a mask to form a second groove. The second groove has a different depth from the first groove.

Exemplary embodiments of the present invention also disclose a method for manufacturing a mold. The method comprises: forming a buffer layer on a substrate; forming a first photosensitive film on the buffer layer; etching the buffer layer and the substrate by using the first photosensitive film as a mask to form a first groove; removing the first photosensitive film; forming a second photosensitive film covering the first groove on the substrate; and etching the substrate by using the second photosensitive film as a mask to form a second groove. The second groove has a different depth from the first groove.

Exemplary embodiments of the present invention also disclose a method for manufacturing a mold. The method comprises forming a photosensitive on a substrate. The photosensitive film comprises a first portion and a second portion having a greater thickness than the first portion. The method also comprises etching an exposed portion of the substrate by using the photosensitive film pattern as a mask to form a preliminary first groove; removing the first portion to expose the substrate; and etching, using the second portion as a mask, the preliminary first groove and the substrate to form a first groove and a second groove. The substrate is etched by using a fluoride acid or an etchant mixture.

Exemplary embodiments of the present invention also disclose a method for manufacturing a mold. The method comprises: forming a buffer layer on a substrate; forming a first photosensitive film on the buffer layer; and exposing and developing the photosensitive film to form a photosensitive film. The photosensitive film comprises a first portion and a second portion having a greater thickness than the first portion. The method further comprises etching, using the photosensitive film pattern as a mask, an exposed portion of the substrate and the buffer layer to form a preliminary first groove; removing the first portion to expose the substrate; and etching, using the second portion as a mask, the preliminary first groove and the substrate to form a first groove and a second groove.

Exemplary embodiments of the present invention also disclose a method for manufacturing a liquid crystal display. The method comprises: forming a lower panel comprising a thin film transistor and a pixel electrode connected to the thin film transistor; forming a light blocking member and a spacer on the lower panel using a roll printing method. The roll printing method is implemented with a mold comprising a first groove having a first depth and a second groove having a second depth. The method further comprises forming an upper panel facing the lower panel; and forming a liquid crystal layer between the upper panel and the lower panel. The upper panel is formed with a common electrode. The first depth is different than the second depth.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of a mold according to an exemplary embodiment of the present invention.

FIG. 2 and FIG. 3 are cross-sectional views sequentially showing a method for manufacturing a mold according to an exemplary embodiment of the present invention.

FIG. 4, FIG. 5 and FIG. 6 are cross-sectional views sequentially showing a method for manufacturing a mold according to another exemplary embodiment of the present invention.

FIG. 7 and FIG. 8 are cross-sectional views sequentially showing a method for manufacturing a mold according to another exemplary embodiment of the present invention.

FIG. 9 and FIG. 10 are cross-sectional views sequentially showing a method for manufacturing a mold according to another exemplary embodiment of the present invention.

FIG. 11 is an equivalent circuit diagram of one pixel in a liquid crystal display according to an exemplary embodiment of the present invention.

FIG. 12 is a layout view of a liquid crystal display according to an exemplary embodiment of the present invention.

FIG. 13 is a cross-sectional view taken along the XIII-XIII line of the liquid crystal display shown in FIG. 12.

FIG. 14 is a layout view of a thin film transistor array panel in the liquid crystal display shown in FIG. 12 except for the pixel electrode.

FIG. 15 is a top plan view of a pixel electrode according to an exemplary embodiment of the present invention.

FIG. 16 is a top plan view of a base electrode of a pixel electrode according to an exemplary embodiment of the present invention.

FIG. 17, FIG. 18, FIG. 19, FIG. 20, and FIG. 21 are cross-sectional views sequentially showing a manufacturing method of the thin film transistor array panel for the liquid crystal display shown in FIG. 12 and FIG. 13.

FIG. 22, FIG. 23, and FIG. 24 are views explaining a method for manufacturing a light blocking member and a spacer by using a mold according to exemplary embodiments of the present invention.

FIG. 25 is a SEM photo showing damage of a buffer layer for etching according to the passage of time according to an exemplary embodiment of the present invention.

### DETAILED DESCRIPTION OF THE ILLUSTRATED EMBODIMENTS

The present invention is described more fully hereinafter with reference to the accompanying drawings in which exemplary embodiments of the invention are illustrated. Embodiments of the invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the sizes and relative sizes of layers and regions may be exaggerated for clarity. Detailed descriptions of well-known functions and structures incorporated herein may be omitted to avoid obscuring the subject matter of the embodiments. Like reference numerals in the drawings denote like elements.

It will be understood that when a first element or layer is referred to as being “on,” “connected to” or “coupled to” another element(s) or layer(s), the first element or layer can be directly on, connected to, or coupled to the other element or layer(s) and/or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that although the terms first, second, third etc. may be used herein to describe various elements, components, regions, layers and/or sections, these elements, components, regions, layers and/or sections should not be limited by these terms. These terms are used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments and is not intended to be limiting of the present invention. As used herein, the singular forms “a,” “an” and “the” can include the plural forms as well, unless the context clearly indicates otherwise. It will be further understood that the terms “comprises” and/or “comprising,” when used in this specification, can specify the presence of stated features, integers, steps, operations, elements, and/or components, but do not necessarily preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result of, for example, manufacturing techniques and/or tolerances, are to be expected. Thus, example embodiments of the present invention should not be construed as limited to the particular shapes of regions illustrated herein but can include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

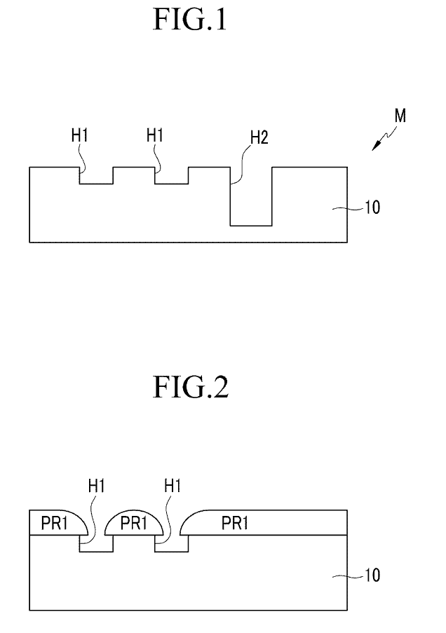

FIG. 1 illustrates a cross-sectional view of a mold M according to exemplary embodiments of the present invention. Mold M may be made of a transparent glass substrate 10 having a plurality of first and second grooves H1 and H2. The first and second grooves H1 and H2 may have different depths and, in some cases, may be separated from one another by a determined distance. In other cases, the first and second grooves H1 and H2 may be connected to one another.

FIGS. 2 to 9 illustrate a method for manufacturing a mold according to exemplary embodiments of the invention.

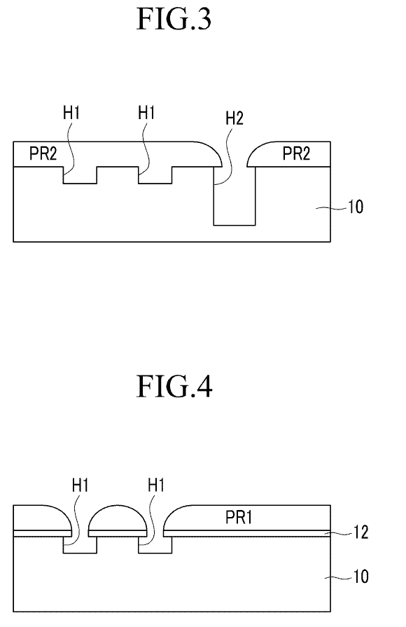

FIG. 2 and FIG. 3 are cross-sectional views sequentially showing a method for manufacturing a mold. Initially, a photosensitive film may be disposed on a transparent glass substrate 10. The photosensitive film can be exposed and developed to form a first photosensitive film pattern PR1, as shown in FIG. 2. The first photosensitive film pattern PR1 may act as a mask when glass substrate 10 is subsequently etched to form first groove H1. In some cases, the first groove H1 may have a depth of approximately 3 μm. In general, the first groove H1 may have any suitable depth. The first groove H1 may be a single groove or a plurality of grooves formed in substrate 10.

Etching of the first photosensitive film may be implemented using any suitable etching process (e.g., dry etching, wet etching). For example, a wet etching process may be implemented using hydrofluoric acid such as HF or an etchant mixture. The composition of the etchant mixture may be approximately 80 to 90 wt % phosphoric acid (H₃PO₄), 0.1 to 5 wt % sulphuric acid, 0.1 to 2 wt % ammonium fluoride with the remainder of the etchant mixture being water such that the total content of the etchant mixture composition is 100 wt %. In some cases, the composition of the etchant may also include nitric acid at about 0.1 to 2 wt %, and in some cases, the composition of the etchant may further include an additive such as an etch control agent, an active interface agent, a metal ion blocking agent, a corrosion preventing agent, and/or a pH control agent. In a wet etching process, an undercut may also be generated under the photosensitive film.

Next, as shown in FIG. 3, the first photosensitive film pattern PR1 may be removed and another photosensitive film may be coated on the substrate 10 and the first groove H1. The second photosensitive film may be exposed and developed to form second photosensitive film pattern PR2. The second photosensitive film pattern PR2 may be used as a mask when substrate 10 is subsequently etched to form the second groove H2. The second groove H2 may be a single groove or a plurality of grooves formed in substrate 10. In some embodiments, the second groove H2 may have a depth of approximately 5 μm. In some cases, the second groove H2 may have a greater depth than the first groove H1.

Next, the second photosensitive film pattern PR2 may be removed such that a mold M having the first and second grooves H1 and H2 is formed, as shown in FIG. 1. In some cases, the formation sequence of the first groove H1 and the second groove H2 may be reversed. For example, second groove H2 may be formed before first groove H1.

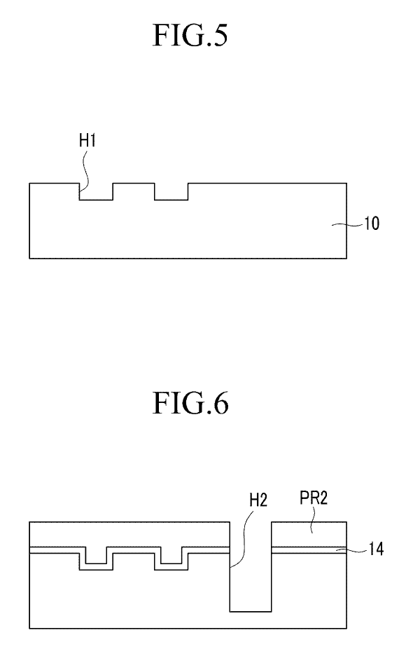

FIG. 4, FIG. 5, and FIG. 6 are cross-sectional views sequentially showing a method for manufacturing a mold according to another exemplary embodiment of the present invention.

According to an alternative exemplary embodiment illustrated in FIGS. 4 to 6, a buffer layer may be utilized for enhancing adhesion of a photosensitive film to the substrate 10. For example, a first buffer layer 12 may initially be disposed on substrate 10. The first buffer layer 12 may be made of a material having a high tolerance against hydrofluoric acid or the etchant mixture for etching the substrate 10 such as a metal of Copper (Cu), Chromium (Cr), Molybdenum (Mo), or Silicon nitride (SiNₓ). Here, SiNₓ may be formed at a temperature of more than 370° C. thereby providing greater density. The first buffer layer 12 enhances adhesion of a photosensitive film pattern such that an etchant mixture may not need to be used.

Next, the first photosensitive film pattern PR1 may be formed on the first buffer layer 12, similar to the step illustrated in FIG. 2. The first buffer layer 12 may subsequently be etched with the first photosensitive film pattern PR1 being used as a mask. If the first buffer layer 12 is a metal buffer layer, a wet etching process may be used. If the first buffer layer 12 is a silicon nitride buffer layer, a dry etching process may be used.

Next, the exposed glass substrate 10 may be etched to form the first groove H1 by using the first photosensitive film pattern PR1 as a mask. The first groove H1 may be wet etched by using hydrofluoric acid or the etchant mixture. In some cases, the first groove H1 may have a depth of approximately 3 μm. In general, the first groove H1 may have any suitable depth. The first groove H1 may be a single groove or a plurality of grooves formed in substrate 10.

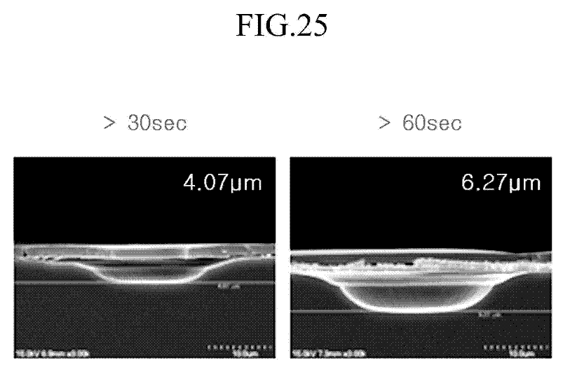

The first groove H1 may be isotropically wet etched such that the first buffer layer may be partially damaged, if the etching of the first groove H1 is executed for a predetermined time. For example, an etchant mixture may be used to etch a molybdenum buffer layer having a thickness of 500 Å. When etching is performed for 30 seconds, the buffer layer may not get damaged; however, if the etching is performed for 60 seconds, the buffer layer may be damaged as shown in FIG. 25.

When the etching is executed for 60 seconds, the buffer layer and the first photosensitive film are damaged leading to a separation, at least partially, between the buffer layer and the first photosensitive film. The extent of damage to the buffer layer may vary depending on a thickness of the buffer layer and a concentration of the etchant mixture. The thickness of the buffer layer and the concentration of the etchant mixture may be determined based on the depth of the groove.

Next, as shown in FIG. 5, the first buffer layer 12 and the first photosensitive layer PR1 may be removed through a lift-off method. A second buffer layer 14 may be formed on substrate 10 and the first groove H1, and a photosensitive film may be coated thereon and exposed and developed to form the second photosensitive film pattern PR2, as shown in FIG. 6. The second buffer layer 14 and the substrate 10 may be etched by using the second photosensitive film pattern PR2 as a mask to form second groove H2. The second groove H2 may be a single groove or a plurality of grooves formed in substrate 10. In some embodiments, the second groove H2 may have a depth of approximately 5 μm.

The second buffer layer 14 and the second photosensitive film pattern PR2 may subsequently be removed through the lift-off method to provide a mold M having first and second grooves H1 and H2 with the different depths, as shown in FIG. 1.

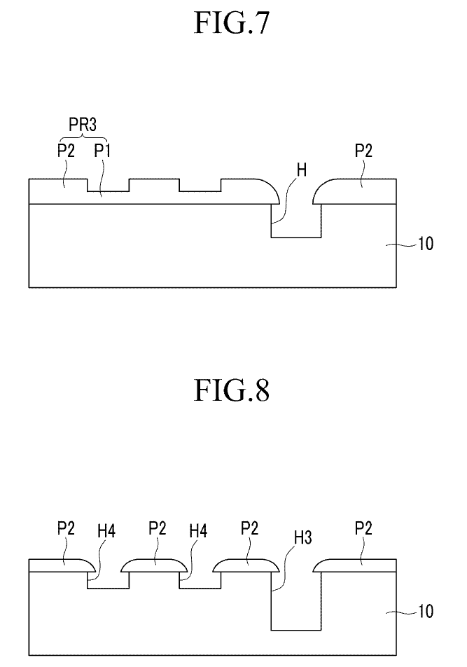

In the above-described exemplary embodiment, two photosensitive films are used, however one photosensitive film may be used, as shown in FIG. 7 to FIG. 10.

FIG. 7 and FIG. 8 are cross-sectional views sequentially showing a method for manufacturing a mold according to another exemplary embodiment of the present invention.

As shown in FIG. 7, a photosensitive film may be disposed on a transparent glass substrate 10. Next, using a light mask including slits or a semi-transparent layer, the photosensitive film may be exposed and developed to form a third photosensitive film pattern PR3 having first and second portions P1 and P2. The first portion P1 may have a different thickness than the second portion P2.

The exposed glass substrate 10 may subsequently be etched using the third photosensitive film pattern PR3 as a mask to form a preliminary third groove H. The etching may be executed by using fluoride acid or any suitable etchant mixture.

Next, as shown in FIG. 8, an ashing process may be executed to remove the first portion P1 of the third photosensitive film pattern PR3, thereby exposing a portion of the glass substrate 10. An upper portion of the second portion P2 having a thickness that is the same as a thickness of the first portion P1 may also be removed. The preliminary third groove H and the exposed glass substrate 10 can then be etched by using the second portion P2 as a mask to complete formation of the mold M including the third and fourth grooves H3 and H4.

The third groove H3 may be a single groove or a plurality of grooves formed in substrate 10. The fourth groove H4 may be a single groove or a plurality of grooves formed in substrate 10.

In exemplary embodiments that utilize a photosensitive film pattern having varying thicknesses at different positions, deep groove H3 may be formed faster than shallow groove H4. Also, the deep groove H3 may be etched twice. For example, the deep groove H3 may, at first, be etched to a depth equal to a thickness of the shallow groove subtracted from the desired total depth of the groove H3. The second etching may provide the desired total depth of groove H3.

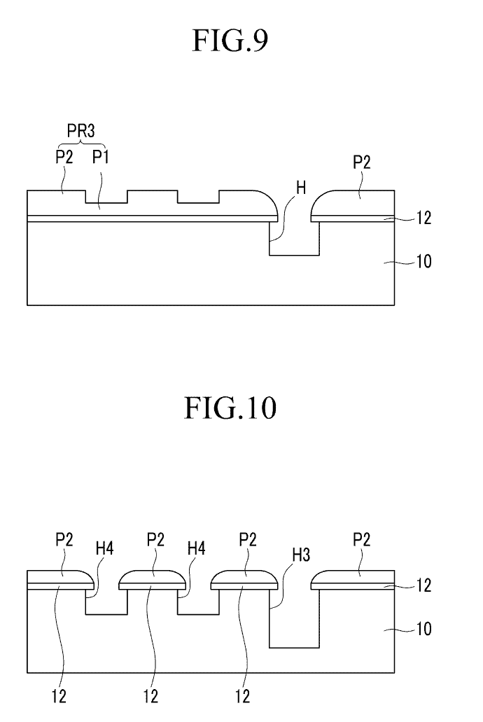

FIG. 9 and FIG. 10 illustrate another exemplary embodiment in which a mold may be formed using a buffer layer shown in FIGS. 4 TO 6.

FIG. 9 and FIG. 10 are cross-sectional views sequentially showing a method for manufacturing a mold.

As shown in FIG. 9, a buffer layer 12 may be disposed on substrate 10. The buffer layer 12 may, for example, enhance adhesion of the photosensitive film pattern to the substrate 10. The buffer layer 12 may be made of a material (e.g., Cu, Cr, Mo, or SiNₓ) having tolerance against hydrofluoric acid or etchant mixtures for etching the substrate 10. If silicon nitride (SiNₓ) is used, SiNₓ may be formed at a temperature of 250° C. or 370° C. thereby providing greater density.

Next, a third photosensitive film pattern PR3 may be formed on the buffer layer 12. The buffer layer 12 and the substrate 10 may be etched to form a preliminary third groove H. Here, the etching may be executed by using fluoride acid or any suitable etchant mixture.

Next, as shown in FIG. 10, an ashing process may be executed to removed the first portion P1 of the third photosensitive film pattern PR3, thereby exposing a portion of the glass substrate 10. An upper portion of the second portion P2 having a thickness that is the same as the thickness of the first portion P1 may also be removed. The preliminary third groove H and the exposed glass substrate 10 can then be etched by using the second portion P2 as a mask to complete formation of the mold including the third and fourth grooves H3 and H4.

The third groove H3 may be a single groove or a plurality of grooves formed in substrate 10. The fourth groove H4 may be a single groove or a plurality of grooves formed in substrate 10.

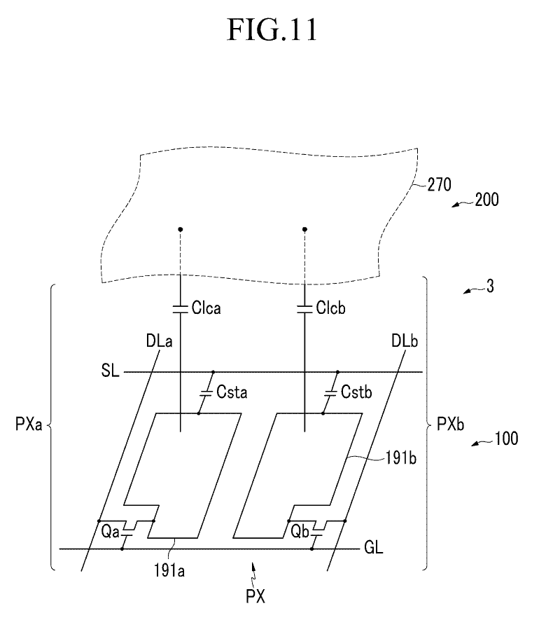

Next, a manufacturing method of a liquid crystal display using the mold of FIG. 1 will be described with reference to FIG. 11 to FIG. 24.

FIG. 11 is an equivalent circuit diagram of one pixel in a liquid crystal display (LCD) according to exemplary embodiments of the present invention.

An LCD may include a plurality of signal lines including, for example, a plurality of gate lines GL, a plurality of pairs of data lines DLa and DLb, and a plurality of storage electrode lines SL. The signal lines may be connected to a plurality of pixels PX. The LCD may include a lower panel 100, an upper panel 200 facing the lower panel 100, and a liquid crystal layer 3 interposed between the upper panel 200 and the lower panel 100.

Each pixel PX can have a pair of subpixels PXa and PXb. Subpixel PXa may be connected to a switching element Qa, a liquid crystal capacitor Clca, and/or a storage capacitor Csta. Subpixel PXb may be connected to a switching element Qb, a liquid crystal capacitor Clcb, and/or a storage capacitor Cstb.

Each switching element (i.e., Qa, Qb) may be a three-terminal element such as a thin film transistor (TFT) and may be arranged on the lower panel 100. Switching elements Qa, Qb may have a control terminal connected to the gate line GL, an input terminal connected to the data line DLa/DLb, and an output terminal connected to the liquid crystal capacitor Clca/Clcb and the storage capacitor Csta/Cstb.

Liquid crystal capacitor Clca may have a first terminal coupled to subpixel electrodes 191a and a second terminal coupled to a common electrode 270. Liquid crystal capacitor Clcb may have a first terminal coupled to subpixel electrodes 191b and a second terminal coupled to a common electrode 270. The liquid crystal layer 3, which is interposed between the two terminals, functions as the dielectric material of the liquid crystal capacitors Clca and Clcb.

The storage capacitors Csta/Cstb may be formed due to an overlap of storage electrode line SL and the subpixel electrodes 191a/191b, and an insulator being interposed between the storage electrode line SL and the subpixel electrodes 191a/191b. A predetermined voltage such as the common voltage Vcom may be applied thereto.

Capacitors Clca and Clcb may be charged with different voltages. For example, a voltage applied to the liquid crystal capacitor Clca may be less or more than a voltage applied to the liquid crystal capacitor Clcb. Voltages of the first and second liquid crystal capacitors Clca and Clcb may be adjusted so that an image viewed from a side of the LCD may appear similar or identical to an image viewed from the front. As a result, exemplary embodiments of the present invention provide an improved visual experience, in particular, for viewers viewing the LCD from the side (i.e., improved side visibility).

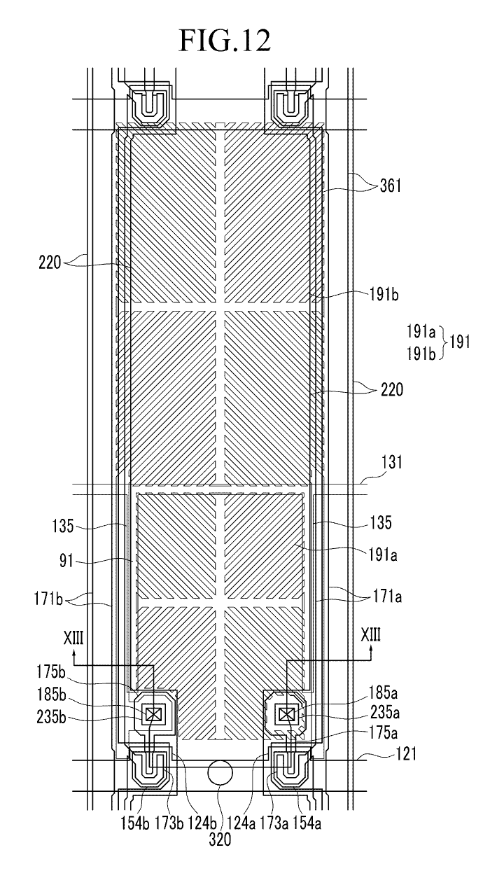

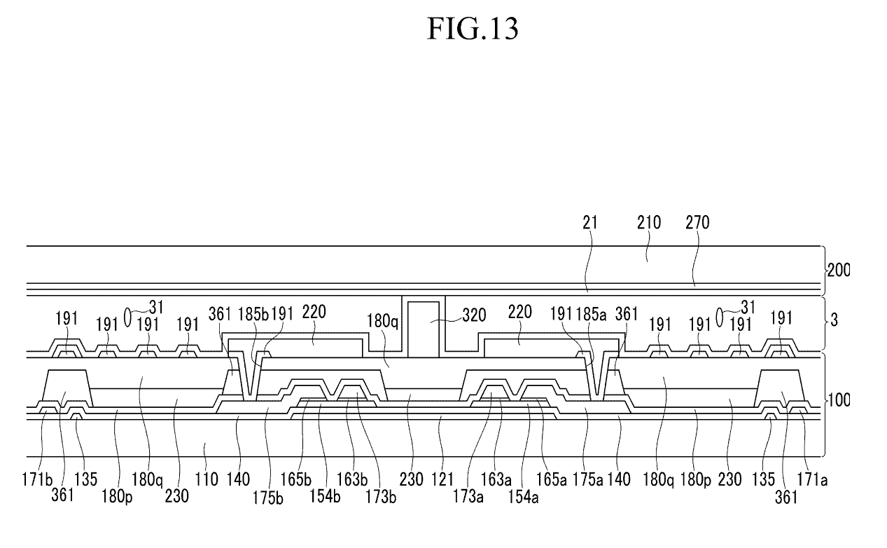

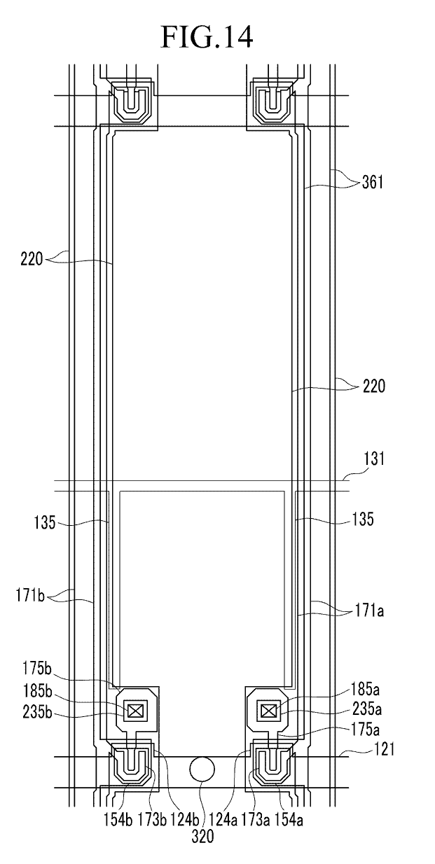

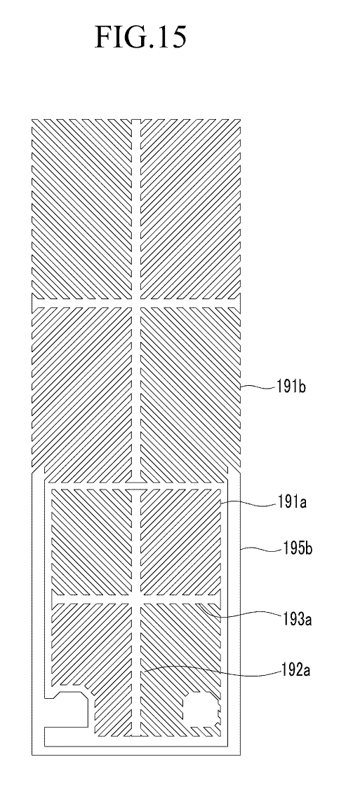

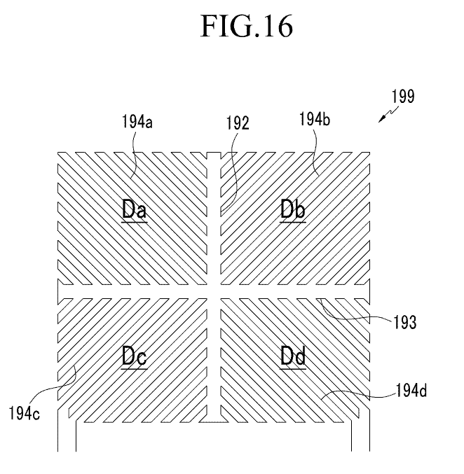

FIG. 12 is a layout view of a liquid crystal display according to an exemplary embodiment of the present invention and FIG. 13 is a cross-sectional view taken along line XIII-XIII shown in FIG. 12. FIG. 14 is a layout view of a TFT array panel of the LCD shown in FIG. 12 except for the pixel electrode. FIG. 15 is a top plan view of a pixel electrode, and FIG. 16 is a top plan view of a base electrode of a pixel electrode according to an exemplary embodiment of the present invention.

As noted above, an LCD may include lower panel 100 and upper panel 200 facing lower panel 100. A liquid crystal layer 3 may be interposed between two display panels 100 and 200. Lower panel 100 may include a plurality of gate lines 121 and a plurality of storage electrode lines 131 and 135 formed on an insulating substrate 110. Each gate line 121 may include a plurality of first and second gate electrodes 124a and 124b protruding upward from the gate line 121. Gate lines 121 may transmit gate signals.

The storage electrode lines may include a stem 131 extending substantially parallel to the gate lines 121 and a plurality of storage electrodes 135 extended from the stem 131. However, the shapes and arrangements of the storage electrode lines 131 and 135 may be modified in various forms.

A gate insulating layer 140 may be formed on the gate lines 121 and the storage electrode lines 131 and 135. A plurality of semiconductors 154a and 154b, preferably made of amorphous or crystallized silicon, may be formed on the gate insulating layer 140.

A plurality of pairs of ohmic contacts including ohmic contact pair 163b and 165b may be formed on the first semiconductor 154b. Ohmic contact pair 163a and 165a may be formed on the first semiconductor 154a. The ohmic contacts 163b and 165b may be formed of a material such as silicide or a n+ hydrogenated amorphous silicon having a high doping of a n-type impurity.

A plurality of pairs of data lines 171a and 171b and a plurality of pairs of first and second drain electrodes 175a and 175b may be formed on ohmic contacts 163b and 165b, and on gate insulating layer 140.

The data lines 171a and 171b may transmit data signals and may extend substantially in a longitudinal direction crossing the gate lines 121 and the stems 131 of the storage electrode lines. The data lines 171a/171b may include a plurality of first/second source electrodes 173a/173b that may extend toward the first/second gate electrodes 124a/124b and may, at least in part, be shaped in a “U” form. The first/second source electrodes 173a/173b may be arranged opposite to the first/second drain electrodes 175a/175b with respect to the first/second gate electrodes 124a/124b.

The data lines 171a and 171b and first and second drain electrodes 175a and 175b may have various shape, sizes, and orientations. For example, a first end of a first drain electrode 175a may be enclosed by the first source electrode 173a and may have a narrow width. The other end of first drain electrode 175b may extend from the first end and may have a wider width (compared to the first end) that may be used to connect to another layer.

The first/second thin film transistors (TFT) Qa/Qb may be formed by the first/second gate electrodes 124a/124b, the first/second source electrodes 173a/173b, the first/second drain electrodes 175a/175b and the first/second semiconductors 154a/154b, which include the channels of the first /second thin film transistors Qa/Qb.

The ohmic contacts 163a, 163b, 165a, and 165b may be interposed between the underlying semiconductor islands 154a and 154b and the overlying data lines 171a and 171b and drain electrodes 175a and 175b. The ohmic contacts 163a, 163b, 165a, and 165b may reduce contact resistance between the semiconductor islands and the overlying data lines 171a and 171b and/or the drain electrode 175a and 175b. The semiconductors 154a and 154b may have a portion that is exposed without being covered by data lines 171a and 171b and drain electrodes 175a and 175b. The semiconductors 154a and 154b may also have a portion exposed between the source electrodes 173a and 173b and the drain electrodes 175a and 175b.

A lower passivation layer 180p, which may be made of silicon nitride or silicon oxide, may be formed on data lines 171a and 171b, drain electrodes 175a and 175b, and exposed portions of the semiconductors 154a and 154b.

A partition 361 may be formed on the lower passivation layer 180p. The partition 361 may be disposed along gate lines 121, data lines 171a and 171b, and the TFTs. A region enclosed by the partition 361 may be of any shape or size. In some cases, the regions enclosed by the partition 361 may be in a rectangular shape. A color filter 230 may be arranged in the region enclosed by the partition 361.

An upper passivation layer 180q may be disposed on the color filter 230. The upper passivation layer 180q may be formed on partition 361 and may planarize the lower panel. The upper passivation layer 180q may be made of an organic material having photosensitivity. In some cases, the upper passivation layer 180q may have a thickness of more than 1.0 μm to reduce coupling between pixel electrode 191 and data lines 171a and 171b although various modifications of the upper passivation layer 180q may be utilized.

The lower passivation layer 180p may prevent a pigment of the color filter 230 from flowing into the exposed semiconductors 154a and 154b.

The upper passivation layer 180q, the color filter 230, and the lower passivation layer 180p may have a plurality of contact holes 185a and 185b exposing the first and second drain electrodes 175a and 175b.

A plurality of pixel electrodes 191 may also be formed on the upper passivation layer 180q. Each pixel electrode 191 may include the first and second subpixel electrodes 191a and 191b that are separated from each other by gap 91. In some cases, gap 91 may have a quadrangular belt shape between the pixel electrodes 191. The first and second subpixel electrodes 191a and 191b each may include a basic electrode 199 shown in FIG. 16.

As shown in FIG. 16, the overall shape of the basic electrode 199 may be a quadrangle and may include a cross-shaped stem having a transverse stem 193 and a longitudinal stem 192 that crosses (e.g., is perpendicular to) the transverse stem 193. The basic electrode 199 may be divided into a first sub-region Da, a second sub-region Db, a third sub-region Dc, and a fourth sub-region Dd by the transverse stem 193 and the longitudinal stem 192. Each of the sub-regions Da-Dd may include a plurality of first to fourth minute branches 194a, 194b, 194c, and 194d.

The first minute branch 194a may obliquely extend from the transverse stem 193 or the longitudinal stem 192 towards the upper-left direction; the second minute branch 194b may obliquely extend from the transverse stem 193 or the longitudinal stem 192 towards the upper-right direction; the third minute branch 194c may obliquely extend from the transverse stem 193 or the longitudinal stem 192 towards the lower-left direction; and the fourth minute branch 194d may obliquely extend from the transverse stem 193 or the longitudinal stem 192 towards the lower-right direction.

The first to fourth minute branches 194a-194d form an angle of about 45 degrees or 135 degrees with the gate lines 121 or the transverse stem 193. Also, the minute branches 194a-194d of two neighboring sub-regions Da-Dd may be crossed.

Although not shown, the width of the minute branches 194a-194d may become wider close to the transverse stem 193 or the longitudinal stem 192. Thus, for example, first minute branch 194a may have a larger width towards the lower left side of Da and a smaller width towards the upper right side of Da.

As noted above, each pixel includes first and second subpixel electrodes 191a and 191b and at least one basic electrode 199. In some cases, an area occupied by the second subpixel electrode 191b may be larger than the area occupied by the first subpixel electrode 191a in the whole pixel electrode 191 area. The second subpixel electrode 191b may have an area that is 1.0 to 2.2 times larger than the area of the first subpixel electrode 191 a, as can be seen in FIG. 15.

First and second subpixel electrodes 191a and 191b may be physically and electrically connected to the first and second drain electrodes 175a and 175b through contact holes 185a and 185b. The first and second subpixel electrodes 191a and 191b may receive data voltages from first and second drain electrodes 175a and 175b.

A spacer 320 and a light blocking member 220 may be disposed on the plurality of pixel electrodes 191. The spacer 320 and the light blocking member 220 may be made of the same material. The light blocking member 220 and/or the spacer 320 may be formed in a region overlapping the TFTs. Although not shown, the light blocking member 220 may be formed in regions surrounding the gate lines 121. The spacer 320 may have a thickness of approximately 4 μm, and the light blocking member 220 may have a thickness of approximately 1.5 μm. In general, various thicknesses may be used for the spacer 320 and the light blocking member 220. The spacer 320 may overlap the gate lines 121 thereby maintaining or increasing the aperture ratio. The spacer 320 may also be formed in a region overlapping the TFTs.

Referring now to the upper panel 200, the upper panel 200 may include a common electrode 270, an insulating surface 210, and an alignment layer 21. The alignment layer 21 may be formed on the common electrode 270. The common electrode 270 may be formed on part of or the whole surface of an insulating substrate 210.

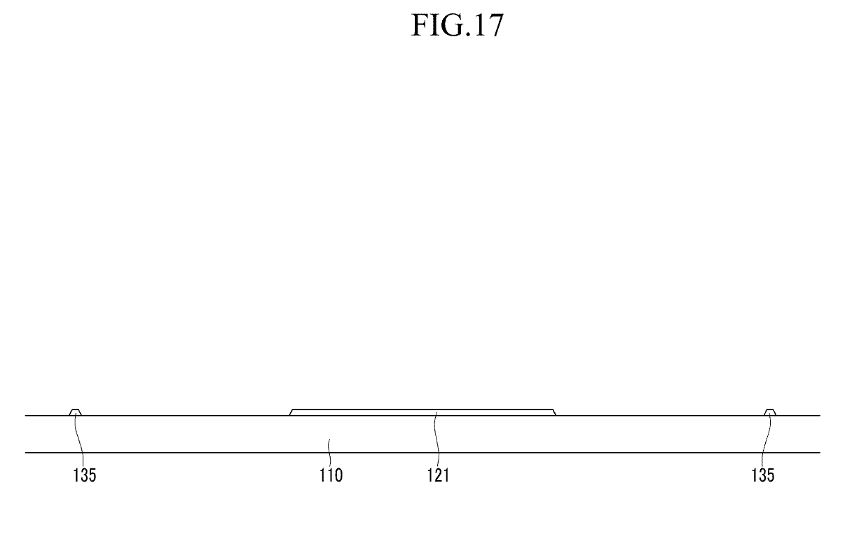

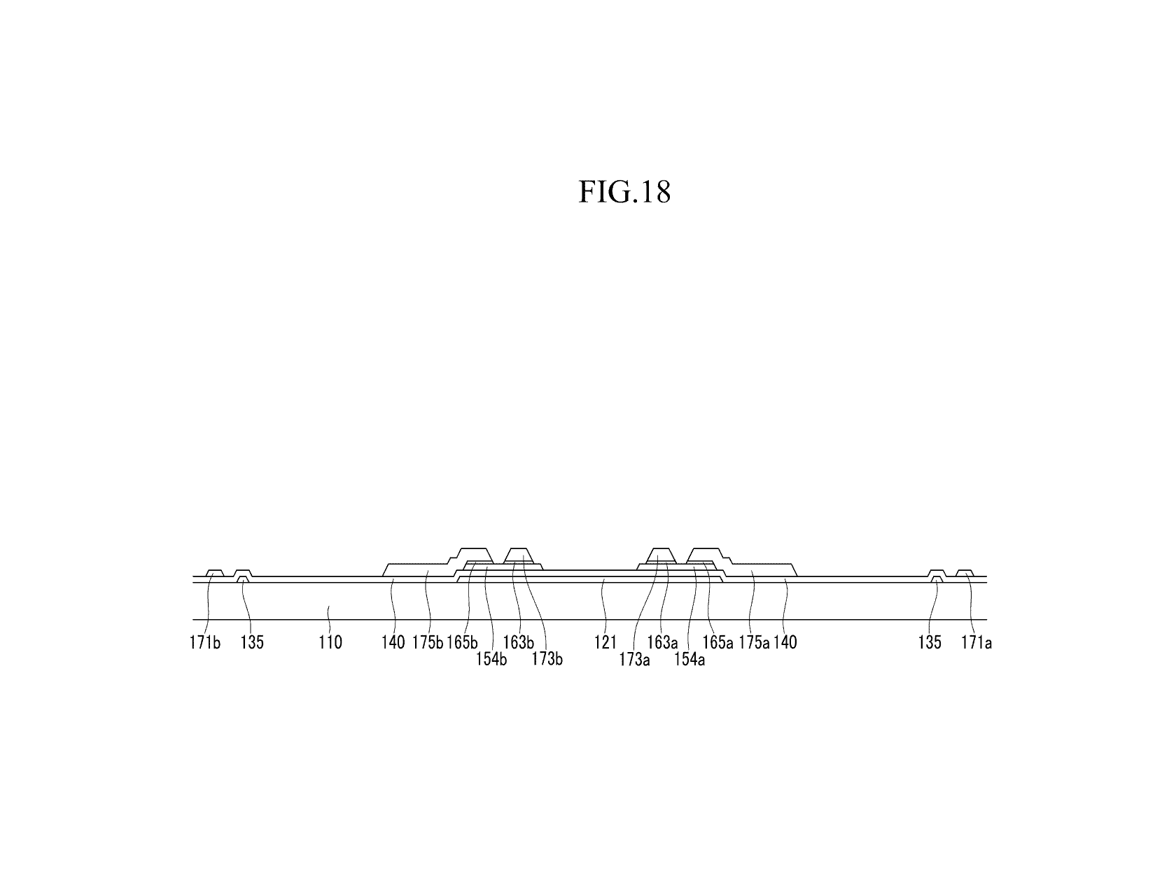

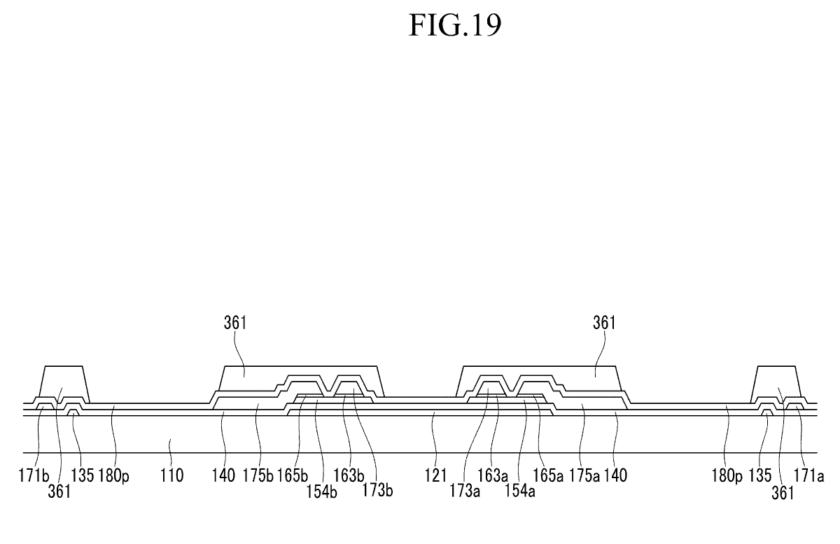

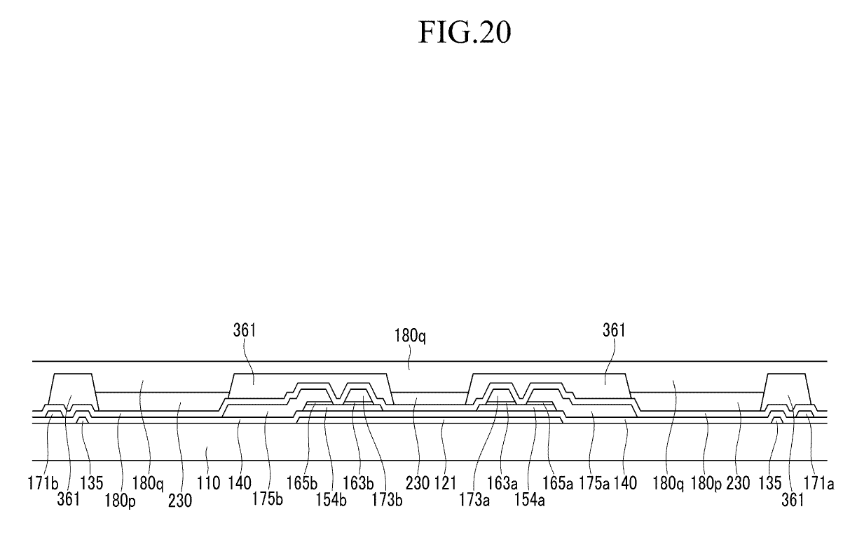

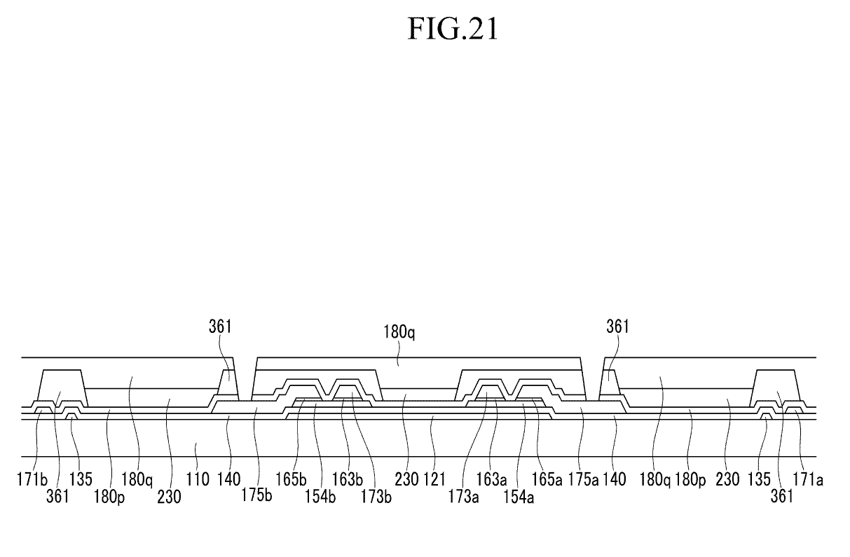

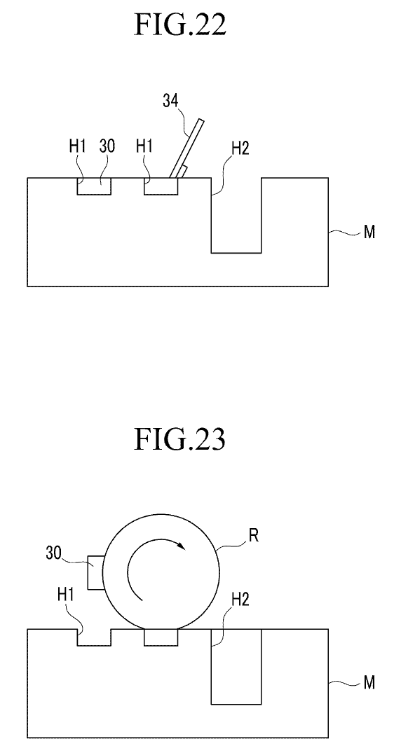

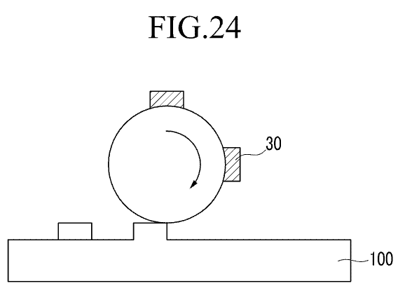

A manufacturing method of a TFT array panel for a liquid crystal display shown in FIG. 12 and FIG. 13 will be described with reference to FIG. 17 to FIG. 24. FIG. 22 to 24 are views explaining a method for manufacturing a light blocking member and a spacer by using a mold according to an exemplary embodiment of the present invention.

A manufacturing method of a TFT array panel for a liquid crystal display shown in FIG. 12 and FIG. 13 will be described with reference to FIG. 17 to FIG. 24. FIG. 22 to 24 are views explaining a method for manufacturing a light blocking member and a spacer by using a mold according to an exemplary embodiment of the present invention.

As shown in FIG. 17, gate lines 121 may be disposed on insulation substrate 110. The gate line may include gate electrodes 124a and 124b. Storage electrodes 135 may also be arranged on substrate 110.

Next, as shown in FIG. 18, silicon oxide may be deposited on the substrate 110, the gate lines 121, and/or storage electrodes 135 to form a gate insulating layer 140. Ohmic contact layer patterns and semiconductors 154a and 154b may be formed by sequentially depositing and patterning an amorphous silicon layer that is not doped with an impurity, and an amorphous silicon layer that is doped with an impurity, and a data conductive layer.

Next, a conductive material may be deposited on the ohmic contact layer patterns, and may be patterned to form data lines 171a and 171b, source electrodes 173a and 173b, and drain electrodes 175a and 175b.

Next, exposed portions of the amorphous silicon layer may be etched by using the source electrodes 173a and 173b and the drain electrode 175a and 175b as an etch mask to form ohmic contact layers 163a, 163b, 165a, and 165b.

The semiconductors 154a and 154b, the ohmic contact layers 163a, 163b, 165a, and 165b, the data lines 171a and 171b, and the drain electrodes 175a and 175b may be formed by using one or more etch masks as described above, however they may also be formed using a photoresist pattern having different thicknesses through a slit mask. In some cases that utilize the photoresist pattern, the ohmic contact layer may have the same plane shape as the data lines and the drain electrodes. Next, as shown in FIG. 19, a lower passivation layer 180p may be formed on the data lines 171a and 171b and the drain electrodes 175a and 175b. An organic insulator may subsequently be deposited on the lower passivation layer 180p, and patterned to form a partition 361.

Next, as shown in FIG. 20, a color filter 230 may be arranged in a filling region defined by partition 361. The color filter 230 may be formed by Inkjet printing. An upper passivation layer 180q made of an organic insulating material may be formed on the color filter 230. Partition 361 may be etched to form contact holes 185a and 185b. During formation, partition 361 may be exposed and the lower passivation layer 180p may be dry-etched. Partition 361 and the lower passivation layer 180p may be etched together such that the inner boundary of the contact holes 185a and 185b may be formed in the partition 361 and that the lower passivation layer 180p may have substantially the same plane shape and boundaries.

As shown in FIG. 13, a pixel electrode 191 may be formed on the upper passivation layer 180q. Next, a light blocking member 220 and a spacer 320 may be formed through a roll printing method on the pixel electrode 191.

The roll printing method is further explained in FIG. 22 to FIG. 24. First, an organic material including black pigments may be coated on mold M (e.g., mold M shown in FIG. 1) to deposit organic material 30 in the first and second grooves H1 and H2. A doctor blade 34 may be used to remove any remaining organic material 30 and/or to planarize the surface of the mold M.

As shown in FIG. 23, the organic material 30 on mold M may be arranged on the surface of the roller by using a roller R. The organic material 30 includes the black pigment, and may be the material to form the color filter 230. The organic material may, in part, be the same material used for an Inkjet.

As shown in FIG. 24, roller R with organic material 30 may be rolled on the substrate 100 of FIG. 21 to deposit the organic material 30 on mold M.

Next, the deposited organic material may be hardened to form spacer 320 and light blocking member 220. The organic material of the first groove H1 may become the light blocking member 220, and the organic material of the second groove H2 may become the spacer 320.

In general, the groove of mold M may be larger than the grooves for the light blocking member 220 and the spacer 320. In some cases, the groove of mold M may be 1.4-1.6 times larger than the grooves for the light blocking member 220 and the spacer 320.

In some cases, organic material 30 may not completely fill the grooves. Accordingly, a size of the grooves and the amount of organic material deposited may need to be determined before hardening the deposited organic material.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A method for manufacturing a mold, comprising:
forming a first photosensitive film on a substrate;
etching the substrate using the first photosensitive film as a mask to form a first groove;
removing the first photosensitive film;
forming a second photosensitive film covering the first groove on the substrate; and
etching the substrate using the second photosensitive film as a mask to form a second groove having a different depth from the first groove.

2. The method of claim 1, wherein
the substrate is etched using a fluoride acid or an etchant mixture.

3. The method of claim 2, wherein
the etchant mixture comprises 80 to 90 wt % phosphoric acid , 0.1 to 5 wt % sulphuric acid, 0.1 to 2 wt % ammonium fluoride, a remaining composition of the etchant mixture being water.

4. The method of claim 1, wherein
the substrate comprises glass.

5. A method for manufacturing a mold, comprising:
forming a buffer layer on a substrate;
forming a first photosensitive film on the buffer layer;
etching the buffer layer and the substrate using the first photosensitive film as a mask to form a first groove;
removing the first photosensitive film;
forming a second photosensitive film covering the first groove on the substrate; and
etching the substrate using the second photosensitive film as a mask to form a second groove having a different depth from the first groove.

6. The method of claim 5, wherein
the buffer layer comprises a metal or silicon nitride.

7. The method of claim 6, wherein
the substrate is etched using a fluoride acid or an etchant mixture.

8. The method of claim 7, wherein
the metal comprises a material having high tolerance against the fluoride acid or the etchant mixture.

9. The method of claim 5, wherein
the substrate comprises glass.

10. A method for manufacturing a mold, comprising:
forming a photosensitive film pattern on a substrate, the photosensitive film pattern comprising a first portion and a second portion having a greater thickness than the first portion;
etching an exposed portion of the substrate using the photosensitive film pattern as a mask to form a preliminary first groove;
removing the first portion to expose the substrate; and
etching, using the second portion as a mask, the preliminary first groove and the substrate to form a first groove and a second groove.

11. The method of claim 10, wherein
the substrate is etched using a fluoride acid or an etchant mixture.

12. The method of claim 11, wherein
the etchant mixture comprises 80 to 90 wt % phosphoric acid, 0.1 to 5 wt % sulphuric acid, 0.1 to 2 wt % ammonium fluoride, a remaining composition of the etchant mixture being water.

13. The method of claim 10, wherein
the substrate comprises glass.

14. A method for manufacturing a mold, comprising:
forming a buffer layer on a substrate;
forming a first photosensitive film on the buffer layer;
exposing and developing the first photosensitive film to form a photosensitive film pattern comprising a first portion and a second portion having a greater thickness than the first portion;
etching, using the photosensitive film pattern as a mask, an exposed portion of the substrate and the buffer layer to form a preliminary first groove;
removing the first portion to expose the substrate; and
etching, using the second portion as a mask, the preliminary first groove and the substrate to form a first groove and a second groove.

15. The method of claim 14, wherein
the buffer layer comprises a metal or silicon nitride.

16. The method of claim 15, wherein
the substrate is etched using a fluoride acid or an etchant mixture.

17. The method of claim 16, wherein
the metal comprises a material having high tolerance against the fluoride acid or the etchant mixture.

18. The method of claim 14, wherein
the substrate comprises glass.

19. A method for manufacturing a liquid crystal display, comprising:
forming a lower panel comprising a thin film transistor and a pixel electrode connected to the thin film transistor;
forming a light blocking member and a spacer on the lower panel using a roll printing method, the roll printing method being implemented with a mold comprising a first groove having a first depth and a second groove having a second depth, the first depth being different than the second depth;
forming an upper panel facing the lower panel, the upper panel being formed with a common electrode; and
forming a liquid crystal layer between the upper panel and the lower panel.

20. The method of claim 19, wherein
the roll printing method comprises:
filling a black color organic material in the first groove and the second groove;
depositing a second organic material on a roller;
depositing the second organic material on the lower panel; and
hardening the second organic material to form the light blocking member and the spacer.

21. The method of claim 19, wherein
the first groove and the second groove are formed 1.4 to 1.6 times larger than the light blocking member and the spacer.
